(19) United States
(12) Patent Application Publication
(10) Pub. No.: US 2026/0180280 A1
(43) Pub. Date: Jun. 25, 2026

(54) LIGHT EMITTING DEVICE, FIRST AND SECOND LIGHT EMITTING DEVICES, AND LIGHT EMITTING MODULE

(71) Applicant: NICHIA CORPORATION, Anan-shi (JP)

(72) Inventor: Naoki SAKA, Tokushima-shi (JP)

(21) Appl. No.: 19/423,808

(22) Filed: Dec. 17, 2025

(30) Foreign Application Priority Data
Dec. 19, 2024 (JP) 2024-223948
Aug. 29, 2025 (JP) 2025-143743

(51) Int. Cl. H01S 5/02345; H01S 5/02253; H01S 5/02315; H01S 5/0239

(52) U.S. Cl. CPC H01S 5/02345; H01S 5/02253; H01S 5/02315; H01S 5/0239

(57) ABSTRACT

A light emitting device includes: light emitting elements each having first and second electrodes, and emitting light in a first direction; a base having first to third element side wiring parts, and first to third power supply side wiring parts, electrically connected to these element side wiring parts, on which the light emitting elements are lined up in a second direction; and first and second wires electrically connected to the light emitting elements on the first electrode side, and a third wire electrically connected to the light emitting elements on the second electrode side. The first and second element side wiring parts are positioned apart from the light emitting elements in the positive second direction, the third element side wiring part is positioned apart from the light emitting elements in the negative second direction. The first to third wires are bonded to the first to third element side wiring parts.

### CROSS-REFERENCE TO RELATED APPLICATIONS

This application claims priority to Japanese Patent Application No. 2024-223948 filed on Dec. 19, 2024, and Japanese Patent Application No. 2025-143743 filed on Aug. 29, 2025, the disclosure of which are hereby incorporated by reference in those entirety.

### BACKGROUND

The present invention relates to a light emitting device, first and second light emitting devices, and a light emitting module.

Japanese Patent Publication No. 2023-46198 discloses a light emitting device comprising a base, plural light emitting elements, and plural wires in which the light emitting elements are disposed on and electrically connected to the base by the wires.

### SUMMARY

A disclosure for solving one issue of realizing a light emitting device with reduced electrical connection resistance will be disclosed.

The disclosure for solving another one issue of realizing a light emitting device with ease of wiring and electrical connection will be disclosed.

The disclosure for solving another one issue of improving the convenience in checking the wire bonding state in a light emitting device will be disclosed.

In the disclosure, multiple objectives among those described above in a compounded manner will also be disclosed.

A light emitting device disclosed by a certain embodiment comprises: plural light emitting elements each having a first electrode and a second electrode, and emitting light in a first direction; a base having plural wiring parts including a first element side wiring part, a second element side wiring part, a third element side wiring part, a first power supply side wiring part electrically connected to the first element side wiring part, a second power supply side wiring part electrically connected to the second element side wiring part, and a third power supply side wiring part electrically connected to the third element side wiring part, on which the plural light emitting elements are lined up in the second direction that is perpendicular to the first direction; and plural wires including a first wire and a second wire electrically connected to the light emitting elements on the first electrode side, and a third wire electrically connected to the light emitting elements on the second electrode side. The first element side wiring part and the second element side wiring part are positioned apart from the light emitting elements in the positive second direction, the third element side wiring part is positioned apart from the light emitting elements in the negative second direction, and the first wire is bonded to the first element side wiring part, the second wire is bonded to the second element side wiring part, and the third wire is bonded to the third element side wiring part.

Another light emitting device disclosed by an embodiment comprises one or plural second light emitting elements each having a first electrode and a second electrode; the base having plural wiring parts including a first element side wiring part, a second element side wiring part, a first power supply side wiring part electrically connected to the first element side wiring part, and a second power supply side wiring part electrically connected to the second element side wiring part, on which the one or plural second light emitting elements are disposed; and plural wires including a first wire electrically connected to the one or plural second light emitting elements on the first electrode side, and a second wire electrically connected to the one or plural second light emitting elements on the second electrode side. The first wire is bonded to the first element side wiring part, and the second wire is bonded to the second element side wiring part. The first light emitting element and the second light emitting element emit light of different peak wavelengths from one another.

A light emitting module disclosed by an embodiment of the invention includes the light emitting device described above, the other light emitting device described above, and a wiring board on which these light emitting devices are mounted.

In at least one of the embodiments of the present invention disclosed, a light emitting device capable of reducing electrical connection resistance can be realized.

### BRIEF DESCRIPTION OF DRAWINGS

FIG. 1 is a perspective view of a light emitting device related to each embodiment.

FIG. 2 is a top view of the light emitting device related to each embodiment.

FIG. 3 is a side view of the light emitting device related to each embodiment.

FIG. 4 is a cross-sectional view of the light emitting device related to each embodiment taken along line IV-IV in FIG. 2.

FIG. 5 is a perspective view showing the constituent elements in the package of a light emitting device related to a first embodiment.

FIG. 6 is a top view showing the constituent elements in the package of the light emitting device related to the first embodiment.

FIG. 7 is a perspective view of a package related to each embodiment.

FIG. 8 is a top view of the package related to each embodiment.

FIG. 9 is a cross-sectional view of the package related to each embodiment taken along line IX-IX in FIG. 8.

FIG. 10 is a cross-sectional view of the package related to each embodiment taken along line X-X in FIG. 8.

FIG. 11 is a top view of a base related to each embodiment.

FIG. 12 is a bottom view of the base related to each embodiment.

FIG. 13 is a cross-sectional view of the base related to each embodiment taken along line XIII-XIII in FIG. 11.

FIG. 14A is an enlarged view enlarging FIG. 13 in the Z direction explaining the stack structure of the base related to each embodiment.

FIG. 14B is a top view of a first insulation member in the stack structure of the base related to each embodiment.

FIG. 14C is a top view of an insulation member disposed under the first insulation member shown in FIG. 14B.

FIG. 14D is a top view of an insulation member disposed under the insulation member shown in FIG. 14C.

FIG. 14E is a bottom view of a second insulation member in the stack structure of the base related to each embodiment.

FIG. 15 is a top view showing a state in which a semiconductor laser element is mounted on a submount related to each embodiment.

FIG. 16 is a side view showing a state in which a semiconductor laser element is mounted on the submount related to each embodiment.

FIG. 17 is a top view showing the constituent elements in the package of a light emitting device relate to a second embodiment.

FIG. 18 is a perspective view of a light emitting module related to a third embodiment.

FIG. 19 is a top view of the light emitting module related to the third embodiment.

### DETAILED DESCRIPTIONS

In the present specification and the scope of claims, a polygon, such as a triangle, rectangle, or the like, includes a shape subjected to processing, such as cutting angles, chamfering, beveling, rounding, or the like. Moreover, the location of such processing is not limited to a corner (an end of a side) of a polygon. Rather, a shape subjected to processing in the intermediate portion of a side will similarly be referred to as a polygon. In other words, any polygon-based shape subjected to partial processing should be understood to be included in the interpretation of a “polygon” disclosed in the present specification and the scope of claims.

This similarly applies to any word describing a specific shape, such as a trapezoidal, circular, recessed, or projected shape, without being limited to a polygon. This also similarly applies to the sides defining such shapes. In other words, even if a corner or intermediate portion of a side is subjected to processing, the term “side” should be interpreted to include the processed portion. To distinguish a “polygon” or “side” that is intentionally not processed from a shape subjected to processing, the shape will be described by adding the phrase “exact,” such as “an exact rectangle.” In the president specification or the scope of claims, terms, such as above/under (upward/downward), right/left, front/rear (forward/rearward), and fore/back merely describe relations among parts or members, such as the relative positions, directions, or orientations. They do not have to match the relations in use.

In some of the drawings, directions such as X, Y, and Z directions are indicated by using arrows. The arrowed directions are coordinated among multiple drawings related to the same embodiments. In the drawings, directions pointed by the X, Y, and Z arrows are positive directions, and the opposite directions are the negative directions. For example, the direction indicated with X in front of the arrow is the X direction and the positive direction. In the present specification, a direction that is the X direction and the positive direction is referred to as “positive X direction,” and the opposite direction “negative X direction.” The “X direction” includes positive and negative directions. This similarly applies to the Y direction and Z direction.

In the present specification, moreover, when describing a certain subject identified as being “one or plural,” both an embodiment having a single subject and an embodiment having plural subjects are collectively described. Accordingly, a description which identifies the subject as “one or plural” supports any of the cases in which an embodiment includes one or plural subjects, at least one subject, and plural subjects.

In the present specification, a description regarding “one or each” subject collectively describes cases in which an embodiment having a single subject and the single subject is described, an embodiment having plural subjects and one of the plural subjects is described, and an embodiment having plural subjects and each of the plural subjects is described. Accordingly, a description regarding “one or each” subject supports any of embodiments in which at least one subject is included and the description applies to the one subject, plural subjects are included and the description applies to at least one of the plural subjects, and plural subjects are included and the description applies to each of the plural subjects.

In the present specification, terms such as “member” and “part/portion” are used to describe a constituent element, for example. The term “member” refers to a subject that is treated as a single physical unit. A subject treated as a single physical unit can be considered as a component in the manufacturing process. The term “part/portion” refers to a subject that does not have to be treated as a single physical unit. The term “part/portion” is used, for example, to capture one part of a member, capture multiple members collectively as one subject, or the like.

A distinction made between the “member” and the “part/portion” described above is not intended to consciously limit the scope of the right in the interpretation of the doctrine of equivalence. In other words, even if there is a constituent element in the scope of claims disclosed as a “member,” the applicant does not recognize it essential to treat the constituent element as a single physical unit in order to apply the present invention.

In the present specification and the scope of claims, when there are multiple pieces of elements having the same designation and a distinction must be made, a word such as “first,” “second,” or the like might occasionally be added to the designation. There might be an occasion where the element designation with the same distinguishing word in the scope of claim is different from that in the specification. For this reason, even if there are constituent elements recited in the scope of claims having the same distinguishing words as in the present specification, it is possible that the subjects identified by them do not match between the present specification and the scope of claims.

For example, in the case in which there are elements that are distinguished by the words, “first,” “second,” and “third,” in the present specification, and only the “first” and “third” elements are recited in a certain claim, they might be distinguished by the words, “first” and “second,” in the claim for readability. In such a case, the elements accompanied by the words, “first” and “second,” in the claim would refer to the subjects accompanied by the words, “first” and third” in the description. This rule applies to not only constituent elements, but also other subjects in a reasonable and flexible manner.

Certain embodiments of the present invention will be explained below.

Specific forms for implementing the present invention will be described with reference to the accompanying drawings. Forms for implementing the present invention are not limited to these specific forms. In other words, these embodiments illustrated are not the only forms for realizing the present invention. The sizes of and relative positions of the members illustrated might be exaggerated for clarity of explanation.

### First Embodiment

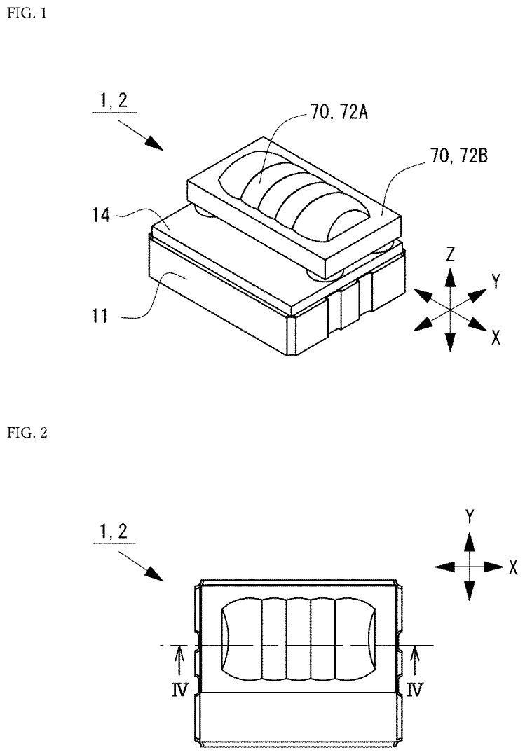

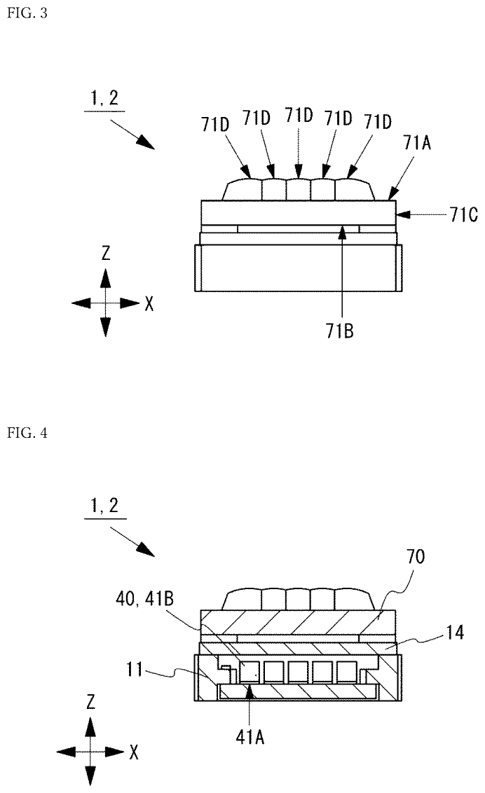

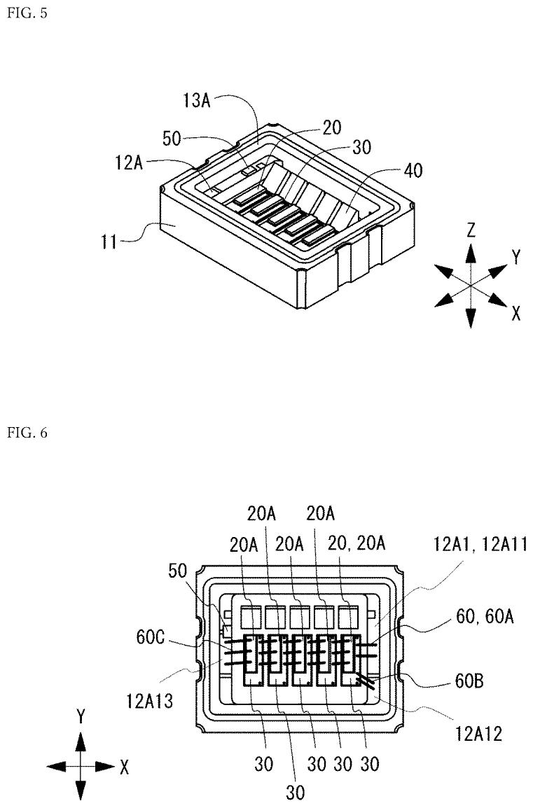

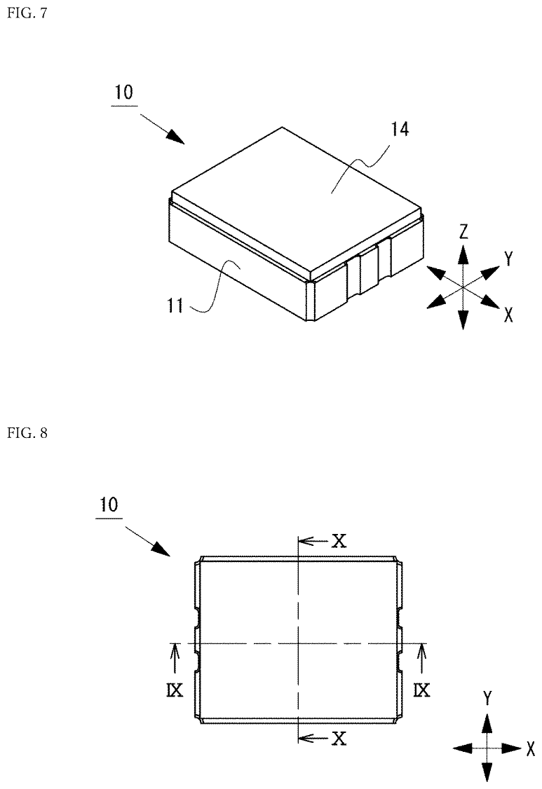

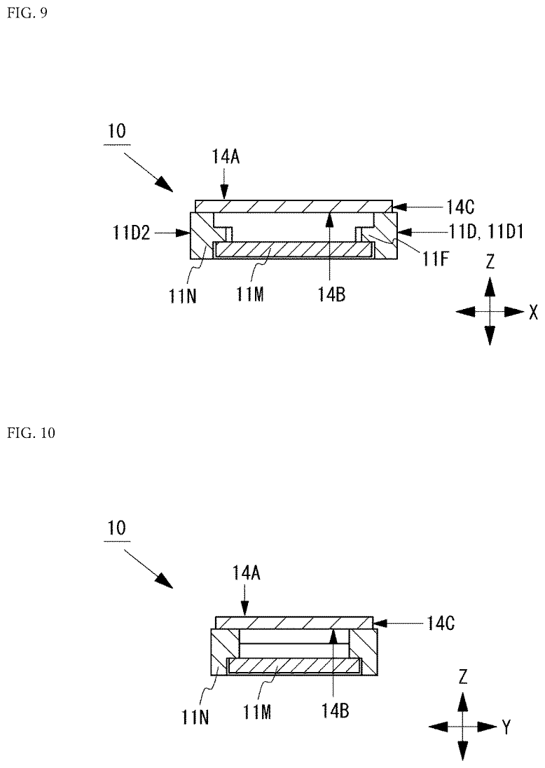

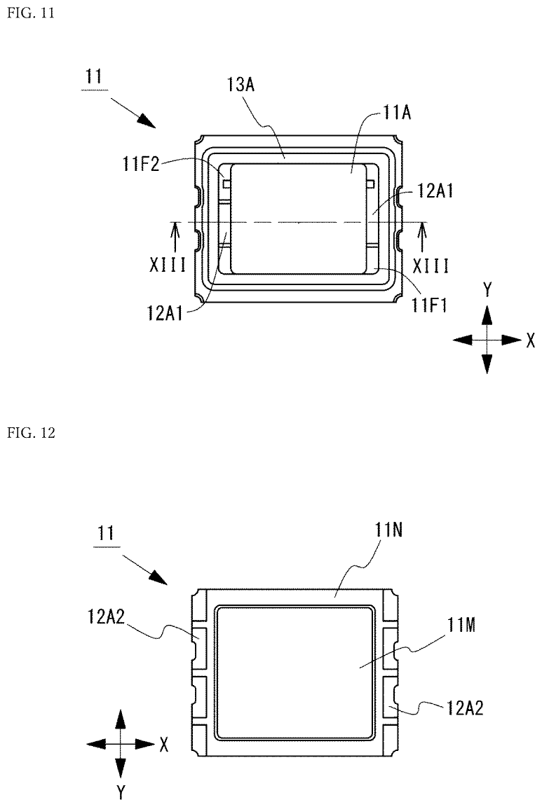

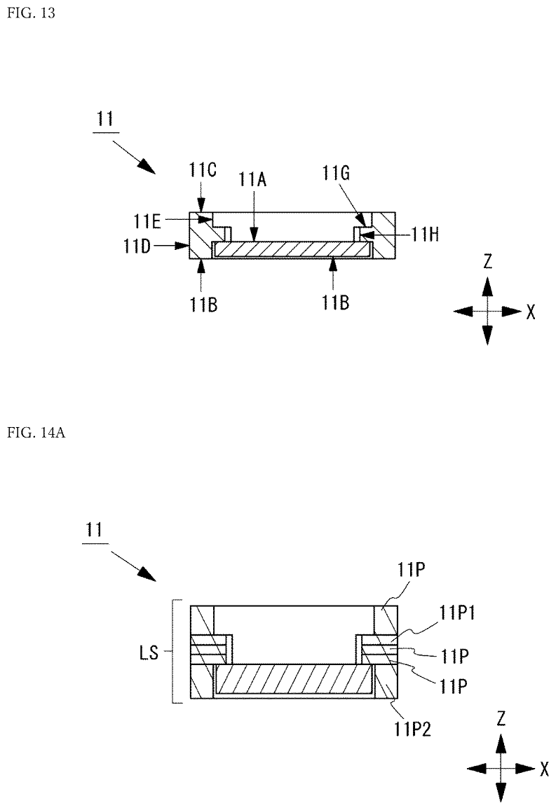

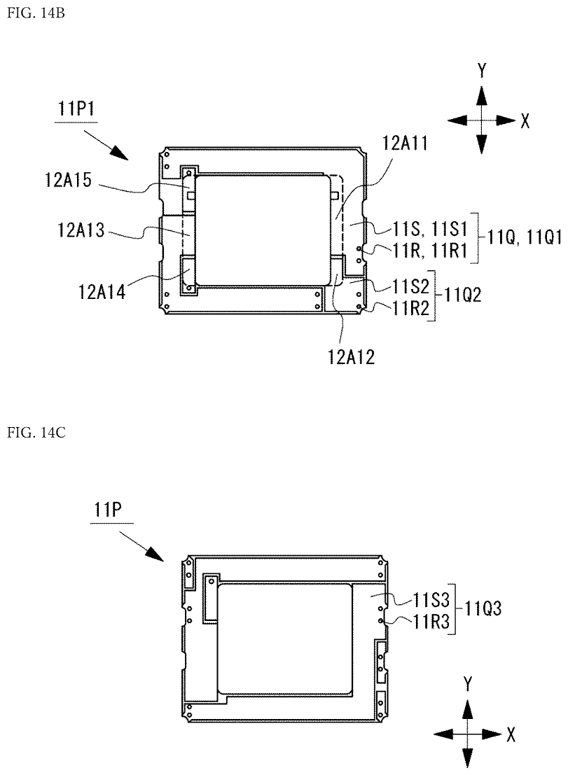

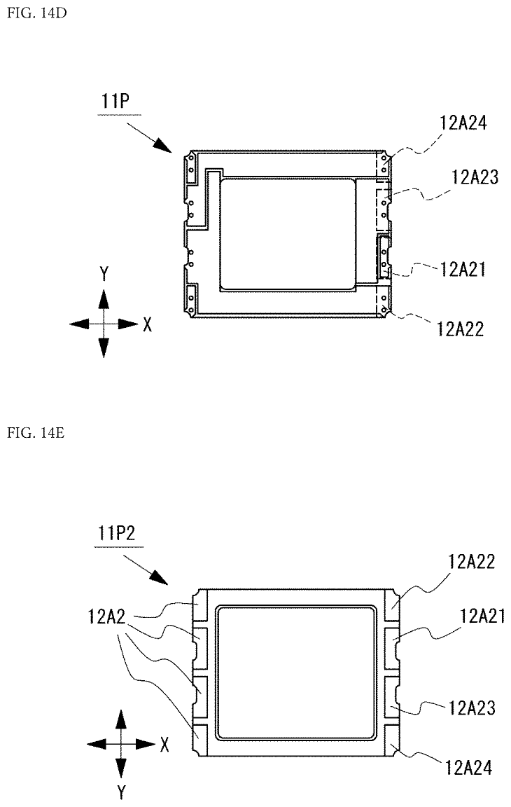

A light emitting device 1 according to a first embodiment will be explained. FIG. 1 to FIG. 16 are drawings explaining an exemplary form of light emitting device 1. FIG. 1 is a perspective view of the light emitting device 1. FIG. 2 is a top view of the light emitting device 1. FIG. 3 is a side view of the light emitting device 1 viewed from the positive Y direction. FIG. 4 is a cross-sectional view of the light emitting device 1 taken along line IV-IV in FIG. 2. FIG. 5 is a perspective view showing the constituent elements in the package 10 of the light emitting device 1. The wires 60 shown in FIG. 6 are not shown in FIG. 5. FIG. 7 is a perspective view of the package 10. FIG. 8 is a top view of the package 10. FIG. 9 is a cross-sectional view of the package 10 taken along line IX-IX in FIG. 8. FIG. 10 is a cross-sectional view of the package 10 taken along line X-X in FIG. 8. FIG. 11 is a top view of a base 11. FIG. 12 is a bottom view of the base 11. FIG. 13 is a cross-sectional view of the base 11 taken along line XIII-XIII in FIG. 11. FIG. 14A is an enlarged view enlarging FIG. 13 in the Z direction explaining the stack structure LS of the base 11. FIG. 14B is a top view of a first insulation member 11P1 in the stack structure LS of the base 11. In FIG. 14B, the positions of the inner lateral faces 11E of the base 11 are indicated with broken lines for ease of understanding the locations of the element side wiring parts. FIG. 14C is a top view of an insulation member 11P disposed directly under the first insulation member 11P1.

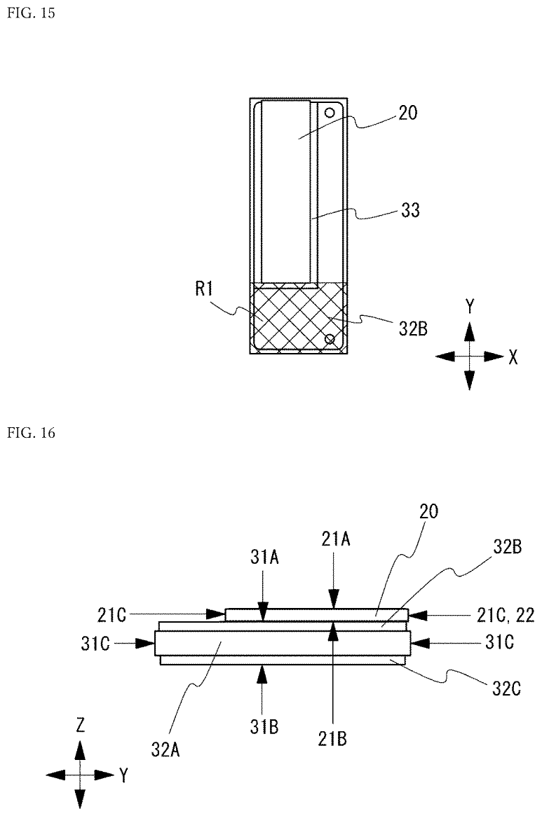

FIG. 14D is a top view of an insulation member 11P disposed directly under the insulation member 11P in FIG. 14C. In FIG. 14D, the locations of first to fourth power supply side wiring parts 12A21 to 12A24 are shown using broken lines for ease of understanding the locations of the power supply side wiring parts. FIG. 14E is a bottom view of a second insulation member 11P2. FIG. 15 is a top view showing the state in which a light emitting element 20 is mounted on a submount 30. In FIG. 15, a region R1 is indicated using a cross-hatching pattern. FIG. 16 is a side view showing the state in which the light emitting element 20 is mounted on the submount 30 viewed from the positive X direction.

A light emitting device 1 includes plural constituent elements. The constituent elements include a package 10, one or plural light emitting elements 20, one or plural submounts 30, one or plural reflecting members 40, one or more protective devices 50, plural wires 60, and an optical member 70.

The light emitting device 1 may include additional constituent elements. For example, the light emitting device 1 may include additional light emitting elements besides the one or plural light emitting elements 20. The light emitting device 1 is allowed to not include a certain constituent element among those listed above.

Each constituent element will be described below.

### Package 10

A package 10 includes a base 11 and a lid 14. The package 10 is formed by bonding the lid 14 to the base 11. In the package 10, an internal space is defined in which other constituent elements are arranged. The internal space is a closed space enclosed by the base 11 and the lid 14. The internal space can be a vacuum or hermetically sealed space.

When viewed from above, the outline of the package 10 is quadrangular. The quadrangular shape can be one having long sides and short sides. In the package 10 shown in the drawings, the long side direction of the quadrangle coincides with the X direction, and the short side direction coincides with the Y direction. The top view outline of the package 10 does not have to be quadrangular.

An internal space where other constituent elements are arranged is formed in the package 10. The upper face 11A of the package 10 is a part of the regions that define the internal space. Each inner lateral face 11E and the lower face 14B of the package 10 are parts of the regions that define the internal space.

A base 11 has a first upper face 11A and a lower face 11B. The base 11 has a second upper face 11C. The base 11 has one or plural outer lateral faces 11D. The base 11 has one or plural inner lateral faces 11E. The one or plural outer lateral faces 11D intersect the second upper face 11C. The one or plural outer lateral faces 11D intersect the lower face 11B. The one or plural inner lateral faces 11E intersect the second upper face 11C.

When viewed from above, the outline of the base 11 is quadrangular. When viewed from above, the outline of the base 11 constitutes the outline of the package 10. When viewed from above, the outline of the first upper face 11A is quadrangular. This rectangular shape can have long sides and short sides. The long side direction of the first upper face 11A is parallel to the long side direction of the outline of the base 11. When viewed from above, the outline of the first upper face 11A does not have to be quadrangular.

When viewed from above, the first upper face 11A is surrounded by the second upper face 11C. The second upper face 11C is an annular face that surrounds the first upper face 11A when viewed from above. The second upper face 11C has a rectangular annular shape. Here, the frame defined by the inner edges of the second upper face 11C will be referred to as the inner frame of the second upper face 11C, and the frame defined by the outer edges of the second upper face 11C will be referred to as the outer frame of the second upper face 11C.

The base 11 has a recess surrounded by the frame made by the second upper face 11C. The recess defines a portion that is depressed downward from the second upper face 11C. The first upper face 11A is a part of the recess. Th one or plural inner lateral faces 11E are parts of the recess. The second upper face 11C is positioned higher than the first upper face 11A.

The base 11 has one or plural stepped portions 11F. A stepped portion 11F has an upper face 11G, and a lateral face 11H that intersects the upper face 11G and extends from the upper face 11G downwards. Here, a stepped portion 11F only has one upper face 11G and one lateral face 11H. The upper face 11G intersects an inner lateral face 11E. The lateral face 11H intersects the first upper face 11A.

The one or each stepped portion 11F is disposed inward of the inner frame of the second upper face 11C when viewed from above. The stepped portion 11F or each stepped portion 11F is formed along an inner lateral face 11E in part or whole when viewed from above. In the base 11, the lateral face 11H is an inner lateral face, but the lateral face 11H and the inner lateral face 11E are different faces. The inner lateral face 11E or each inner lateral ace 11E and the lateral face 11H or each lateral face 11H are perpendicular to the first upper face 11A. Here, being perpendicular tolerates an error of up to ±3 degrees.

The one or plural stepped portions 11F can include a first stepped portion 11F1 and a second stepped portion 11F 2. The first stepped portion 11F1 and the second stepped portion 11F2 are disposed at positions such that the respective lateral faces 11H oppose one another. The first stepped portion 11F1 and the second stepped portion 11F2 are disposed along the short-length sides of the inner frame of the second upper face 11C.

The base 11 has a base part 11M and a frame part 11N. The base part 11M and the frame part 11N may be members made of different materials. The base 11 can be composed of a base member corresponding to the base part 11M and a frame member corresponding to the frame part 11N.

The base part 11M includes the first upper face 11A. The frame part 11N includes the second upper face 11C. The frame part 11N includes one or plural outer lateral faces 11D and one or plural inner lateral faces 11E. The frame part 11N includes one or plural stepped portions 11F.

The lower face of the base part 11M constitutes a portion of or the entire region of the lower face 11B of the base 11. In the case in which the lower face of the base part 11M constitutes a portion of the lower face 11B of the base 11, the lower face of the frame part 11N constitutes the remaining region of the lower face 11B of the base.

The base 11 has plural wiring parts 12A. The wiring parts 12A include one or plural first wiring parts 12A1 and one or plural second wiring parts 12A2. The one or plural first wiring parts 12A1 are disposed in the internal space of the package 10. The one or plural second wiring parts 12A2 are disposed on the outer surface of the package 10.

The one or each first wiring part 12A1 is disposed on the upper face 11G of a stepped portion 11F. The base 11 has one or plural first wiring parts 12A1 disposed on the upper face 11G of a first stepped portion 11F1. The base 11 has one or plural first wiring parts 12A1 disposed on the upper face 11G of a second stepped portion 11F 2.

The one or each second wiring part 12A2 is disposed on the lower face 11B of the package 10. The one or each second wiring part 12A2 is disposed on the lower face of the frame part 11N. The second wiring part 12A2 may be disposed on the outer surface that is different from the lower face 11B of the package 10.

The base 11 has one or plural second wiring parts 12A2 disposed on the lower face 11B of the base 11 in the region that includes the upper face 11G of a first stepped portion 11F1 when the base 11 is divided into two regions by an imaginary line that passes the lateral face 11H of the first stepped portion 11F1 and is parallel to the lateral face 11H when viewed from above.

The base 11 has one or plural second wiring parts 12A2 disposed on the lower face 11B of the base 11 in the region that includes the upper face 11G of a second stepped portion 11F2 when the base 11 is divided into two regions by an imaginary line that passes the lateral face 11H of the second stepped portion 11F2 and is parallel to the lateral face 11H when viewed from above.

In the base 11, the first wiring part 12A1 or each first wiring part 12A1 is electrically connected to a second wiring part 12A2. The one or plural first wiring parts 12A1 are electrically connected to the second wiring parts 12A2 that are different from one another.

The base 11 has a stack structure LS in which plural insulation members 11P are stacked. The frame part 11N of the base 11 can have the stack structure. The stack structure LS has plural via wiring 11Q. The first wiring part 12A1 and the second wiring part 12A2 are disposed on the surface of the stack structure LS. The first wiring part 12A1 and the second wiring part 12A2 are electrically connected using the via wiring 11Q.

The via wiring 11Q has a via part 11R that goes through the insulation member 11P in the stacking direction, and a wiring layer 11S connected to the via part 11R. The wiring layer 11S is disposed between two insulation members 11P. The wiring layer 11S extends in the planar direction of the insulation members 11P which is perpendicular to the stacking direction.

The insulation members 11P include a first insulation member 11P1 on which a first wiring part 12A1 is disposed and a second insulation member 11P2 on which a second wiring part 12A2 is disposed. The first wiring part 12A1 is disposed on the upper face of the first insulation member 11P1. The second wiring part 12A2 is disposed on the lower face of the second insulation member 11P2.

The base 11 has a bonding pattern 13A. The bonding pattern 13A is disposed on the second upper face 11C. The bonding pattern 13A has an annular shape. The bonding pattern 13A has a quadrangular annular shape. The first upper face 11A is surrounded by the bonding pattern 13A when viewed from above.

The base 11 can be formed, for example, by using a ceramic as a primary material. Examples of ceramics for use as a primary material for the base 11 include aluminum nitride, silicon nitride, aluminum oxide, or silicon carbide.

Here, a primary material is a material occupying the largest portion in mass or volume of a subject formed body. In the case in which a subject formed body is made of a single material, the material is the primary material. In other words, a given material being a primary material of a subject includes the case in which the material constitutes 100% of the subject.

The base 11 may be formed with a base member and a frame member that are formed of primary materials that are different from one another. The base member can be formed, for example, by using a material that excels in heat dissipation, such as a metal, a composite containing a metal, graphite, diamond, or the like. A metal for use as a primary material for the base member is, for example, copper, aluminum, or iron. A composite containing a metal for use as a primary material for the base member is, for example, molybdenum copper or tungsten copper. The frame member can be formed by using as a primary material any of the ceramics listed as a primary material for the base 11 described above.

The wiring parts 12A can be formed, for example, by using a metal as a primary material. Examples of metal materials for use as a primary material for the wiring parts 12A include simple metals, such as Cu, Ag, Ni, Au, Ti, Pt, Pd, Cr, W, and the like, or alloys containing these metals. The wiring parts 12A may include one or plural metal layers, for example.

The bonding pattern 13A can be formed by using, for example, a metal material as the primary material. Examples of metal materials for a primary material for the bonding pattern 13A includes simple metals, such as Cu, Ag, Ni, Au, Sn, Ti, Pd, and the like, or alloys containing these metals. The bonding pattern 13A may include one or plural metal layers, for example.

A lid 14 has an upper face 14A and a lower face 14B. The lid 14 further has one or plural lateral faces 14C. The lid 14 is a cuboid having a flat sheet shape. The lid 14 does not have to be a cuboid.

The lid 14 is bonded to the base 11. The lower face 14B of the lid 14 is bonded to the second upper face 11C of the base 11. The lid 14 is bonded to the bonding pattern 13A of the base 11. The lid 14 is bonded to the base 11 via an adhesive.

The lid 14 has light transmissivity to allow light to pass through. Here, light transmissivity means a light transmittance of 80% or higher for the light that becomes incident on the lid 14. The lid 14 may have a non-transmissive region (region not having light transmissivity) in part.

The lid 14 can be formed by using glass as a primary material. The lid 14 may be formed by using, for example, sapphire as a primary material.

### Light Emitting Element 20

A light emitting element 20 has an upper face 21A, a lower face 21B, and lateral faces 21C. The shape of the upper face 21A is quadrangular. This quadrangular shape has long sides and short sides. When viewed from above, the outline of the light emitting element 20 is quadrangular. This quadrangular shape has long sides and short sides. The shape of the upper face 21A and the top view outline of the light emitting element 20 are not limited to this.

A light emitting element 20 has a light emission face 22 through which light is output. For example, one of the lateral faces 21C can be a light emission face 22. The lateral face 21C which serves as the light emission face 22 intersects a short side of the upper face 21A. Moreover, for example, the upper face 21A can be a light emission face 22. The light emitting element 20 has one or plural light emission faces 22.

A light emitting element 20 has two electrodes. The two electrodes can be individually disposed on two opposing faces. For example, one of the two electrodes is disposed on the upper face 21A, and the other electrode on the lower face 21B. Both electrodes may be disposed on one face. The two electrodes are anode and cathode electrodes.

For a light emitting element 20, for example, a red light emitting element can be employed. For example, for a light emitting element 20, a green light emitting element can be employed. For example, for a light emitting element 20, a blue light emitting element can be employed. For a light emitting element 20, one that emits light of another color or wavelength may be employed.

Here, blue light refers to light whose peak wavelength falls within a 420 nm to 494 nm range. Green light refers to light whose peak wavelength falls within a 495 nm to 570 nm range. Red light refers to light whose peak wavelength falls within a 605 nm to 750 nm range.

Examples of light emitting elements 20 that emit blue or green light include light emitting elements that include nitride semiconductors. For the nitride semiconductors, for example, GaN-based semiconductors, such as GaN, InGaN, AlGaN, or the like can be employed. Examples of light emitting elements 20 that emit red light include those that include InAlGaP-based semiconductors, GaInP-based semiconductors, or GaAs-based semiconductors, such as GaAs, AlGaAs, or the like.

For a light emitting element 20, for example, a semiconductor laser element can be employed. For the light emitting element 20, a single emitter semiconductor laser element having a single emitter can be employed. For the light emitting element 20, a multi-emitter semiconductor laser element having multiple emitters can be employed. Not limited to a semiconductor laser element, a light emitting diode or the like may be employed for the light emitting element 20.

Here, as one example of light emitting element 20, a semiconductor laser element will be described.

A semiconductor laser element emits laser light which has directivity. Divergent light that spreads is emitted from the light emission face 22 of a semiconductor laser element. The light emitted from a semiconductor laser element forms an elliptical far field pattern (hereinafter referred to as “FFP”) in a plane parallel to the light emission face 22. An FFP represents the shape and the light intensity distribution of the emitted light at a position that is distant from the light emission face of a semiconductor laser element.

The light passing the center of the elliptical FFP, in other words, the light having the peak intensity in the light intensity distribution of the FFP will be referred to as the light advancing or travelling along the optical axis. The light having an intensity of at least 1/e² relative to the peak intensity value in the light intensity distribution of an FFP will be referred to as the “main portion” of the light.

The shape of an FFP of the light emitted from a semiconductor laser element in a plane parallel to the light emission face 22 is elliptical which is longer in the stacking direction than the direction perpendicular to the stacking direction. The stacking direction refers to the direction in which semiconductor layers including an active layer are stacked in the semiconductor laser element. The direction perpendicular to the stacking direction in other words is the planar direction of the semiconductor layers. The major axis direction of the elliptical shape of an FFP can also be referred to as the fast axis direction of the semiconductor laser element and the minor axis direction the slow axis direction of the semiconductor laser element.

Based on the light intensity distribution of an FFP, the divergence angle of the light having the 1/e² intensity of the peak intensity is referred to as the beam divergence angle of the light from the semiconductor laser element. Here, the divergence angle is represented by the angle formed by the light having the peak intensity (light along the optical axis) and the light having the 1/e² intensity of the peak intensity. The beam divergence angle can be obtained, for example, from the light intensity having one half of the peak intensity besides the 1/e² intensity of the peak intensity. In the present specification, when it is simply called the “beam divergence angle,” it refers to the beam divergence angle formed by the light having the 1/e² intensity of the peak intensity.

The fast axis direction divergence angle of the light emitted from a semiconductor laser element can be 20° or larger and smaller than 80°. The slow axis direction divergence angle of the light emitted from the semiconductor laser element can be larger than 0° and 30° at most. The fast axis direction divergence angle of the light is larger than the slow axis direction divergence angle.

For example, the fast axis direction divergence angle of blue light from a semiconductor laser element can be 30° or larger and smaller than 60°, and the slow axis direction divergence angle can be 5° or larger and smaller than 15°. For example, the fast axis direction divergence angle of green light from a semiconductor laser element can be 30° or larger and smaller than 60°, and the slow axis direction divergence angle can be larger than 0° and smaller than 30°. For example, the fast axis direction divergence angle of red light from a semiconductor laser element can be 40° or larger and smaller than 80°, and the slow axis direction divergence angle can be 5° or larger and smaller than 20°.

### Submount 30

A submount 30 has an upper face 31A, a lower face 31B, and one or plural lateral faces 31C. The upper face 31A can be considered as a mounting face on which other constituent elements are mounted. The shape of the upper face 31A is quadrangular. This quadrangular shape of the upper face 31A can have short sides and long sides. The shape of the upper face 31A does not have to be quadrangular.

The outline of a submount 30 when viewed from above is quadrangular. The quadrangular shape of the outline of the submount 30 can have short sides and long sides. The outline of the submount 30 when viewed from above does not have to be quadrangular. The submount 30, when viewed from above, can have an outline in which the length in one direction (hereinafter referred to as the short-length direction) is smaller than the length in the direction perpendicular thereto (hereinafter referred to as the long-length direction). In the submount 30 illustrated, the short-length direction coincides with the X direction and the long-length direction coincides with the Y direction.

A submount 30 can include a substrate 32A and an upper metal member 32B. The submount 30 can further include a lower metal member 32C. The upper metal member 32B is disposed on the upper face side of the substrate 32A. The lower metal member 32C is disposed on the lower face side of the substrate 32A. The submount 30 further has a wiring layer 33. The wiring layer 33 is disposed on the upper metal member 32B.

The substrate 32A has insulation properties. The substrate 32A is formed, for example, with silicon nitride, aluminum nitride, or silicon carbide. A ceramic which dissipates heat relatively well (has high thermal conductivity) can suitably be selected as a primary material for the substrate 32A.

For the primary material for the upper metal member 32B, a metal, such as copper, aluminum, or the like is used. The upper metal member 32B has one or plural metal layers. The upper metal member 32B can have plural metal layers made of different metals as their primary materials.

For the primary material for the lower metal member 32C, a metal, such as copper, aluminum, or the like is used. The lower metal member 32C has one or plural metal layers. The lower metal member 32C can have plural metal layers made of different metals as their primary materials.

The wiring layer 33 can be formed with metal. For example, the wiring layer 33 can be formed by using AuSn solder (AuSn metal layer).

For example, the short side direction or the short-length direction length of a submount 30 is 700 μm to 900 μm. The long side direction or the long-length direction length of the submount 30 is 2000 μm to 2200 μm. The difference between the length in the long-length direction and the length in the short-length direction is 1200 μm to 1600 μm.

For example, the thickness of a submount 30 (the width in the direction perpendicular to the upper face 31A) is 250 μm to 350 μm. For example, the thickness of the substrate 32A is 150 μm to 250 μm. For example, the thickness of the upper metal member 32B is 30 μm to 80 μm. For example, the thickness of the lower metal member 32C is 30 μm to 80 μm. For example, the thickness of the wiring layer 33 is 1.5 μm to 3.5 μm.

### Reflecting Member 40

A reflecting member 40 has a lower face 41A and a light reflecting face 41B that reflects light. The light reflecting face 41B is oblique to the lower face 41A. The straight line connecting the lower end and the upper end of the light reflecting face 41B is oblique to the lower face 41A. The oblique angle formed by the light reflecting face 41B and the lower face 41A will be referred to as the oblique angle of the light reflecting face 41B.

The light reflecting face 41B is a flat face. The light reflecting face 41B may be a curved face. The oblique angle of the light reflecting face 41B is 45 degrees. The oblique angle of the light reflecting face 41B does not have to be 45 degrees.

For the primary material for the reflecting member 40, glass, metal, or the like can be used. A heat resistant material can be suitably used as the primary material for the reflecting member 40. For the primary material, for example, glass such as quartz or BK7 (borosilicate glass), metals such as Al or the like can be used. The reflecting member 40 can be alternatively formed by using Si as a primary material.

Employing a reflecting material such as Al as the primary material allows the primary material to serve as the light reflecting face 41B. Instead of forming the light reflecting face 41B with the primary material, the reflecting member 40 may be generally shaped with a primary material, and a light reflecting face 41B formed on the surface thereof. In this case, the light reflecting face 41B can be formed by using a metal layer, such as Ag, Al, or the like, or a dielectric multilayer film, such as Ta₂O₅/SiO₂, TiO₂/SiO₂, Nb₂O₅/SiO₂, or the like.

The light reflecting face 41B has a reflectance of 90% or higher for the peak wavelength of the light irradiated on the light reflecting face 41B. The reflectance may be 95% or higher. The reflectance can be set to 99% or higher. The reflectance is 100% or lower, or lower than 100%.

### Protective Device 50

A protective device 50 has an upper face, a lower face, and one or plural lateral faces. The shape of the protective device 50 is a cuboid. The shape of the protective device 50 does not have to be a cuboid.

The protective device 50 is provided for preventing a specific element (e.g., light emitting element) from being destroyed by excess current. One example of protective device 50 is a Zener diode. For the Zener diode, one formed with Si can be employed.

### Wire 60

A wire 60 is a linear conductive material having bonding parts at both ends. The bonding parts at both ends are used to achieve connections with other constituent elements. A wire 60 is, for example, a metal wire. For example, gold, aluminum, silver, copper, or the like can be used as the metal.

### Optical Member 70

An optical member 70 has an upper face 71A, a lower face 71B, and one or plural lateral faces 71C. The optical member 70 applies an optical action to the light that becomes incident on the optical member 70. The optical actions applied to the light by the optical member 70 include condensing, collimation, dispersion, polarization, diffraction, multiplexing, optical guiding, reflection, wavelength conversion, and the like.

An optical member 70 has an optical action face that applies an optical action. The upper face 71A, the lower face 71B, or a lateral face 71C can be an optical action face. The optical action face may be located at a position other than the upper face 71A, the lower face 71B, and the lateral faces 71C. For example, an optical action face may be formed inside of the optical member 70, rather than on the surface.

An optical member 70 can have one or plural lens faces 71D. A lens face 71D is an optical action face of the optical member 70. An optical member 70 having a lens face 71D may be called a lens member. The light that passes through the lens face 71D and exits the optical member 70 is subjected to an optical action by the optical member 70, such as condensing, dispersion, or collimation. For example, the optical member 70 is a collimating lens which changes the light that became incident on the optical member 70 to collimated light to be output.

The lens face 71D or each lens face 71D is disposed on the upper face 71A side. The lens face 71D may be disposed on the lower face 71B side. The upper face 71A and the lower face 71B are flat faces. The lens face 71D or each lens face 71D intersects the upper face 71A. When viewed from above, the lens face 71D or each lens face 71D is enclosed by the upper face 71A.

When viewed from above, the outline of the optical member 70 is quadrangular. The top view outline of the optical member 70 does not have to be quadrangular. The lower face 71B is a flat face. No lens face 71D is formed on the lower face 71B side of the optical member 70. The shape of the lower face 71B is quadrangular. The shape of the lower face 71B does not have to be quadrangular.

In the optical member 70, the portion that overlaps a lens face 71D when viewed from above is referred to as a lens part 72A. In the optical member 70, the portion that overlaps the upper face 71A when viewed from above is referred to as the non-lens part 72B. The lower face 71B has a region that constitutes the lower face of the lens part 72A or each lens part 72A and a region that constitutes the lower face of the non-lens part 72B.

An optical member 70 can have plural lens faces 71D that are continuously linked in one direction. When viewed from above, the direction in which the lens faces 71D are arranged will be referred to as the lens coupling direction. In the optical member 70 illustrated, the coupling direction coincides with the X direction.

The lens faces 71D are formed such that the vertices of the lens faces 71D are positioned on a straight line. The imaginary line connecting the vertices is parallel to the lower face 71B of the optical member 70. The parallel here includes an error of up to ±5 degrees.

Two or more lens faces 71D, which are some or all of the lens faces 71D, can have the same curvature. All of the lens faces 71D can have the same curvature.

An optical member 70 has light transmissivity. The optical member 70 has a transmittance of 80% or higher for the peak wavelength of the light that becomes incident on the optical member 70. The optical member 70 may have a light transmissive region and a region that is not light transmissive (hereinafter referred to as a non-transmissive region). In the non-transmissive region, the transmittance for the peak wavelength of the light incident on the optical member 70 is 50% or lower. The optical member 70 can be formed, for example, by using glass such as BK7.

A light emitting device 1 will be described next.

### Light Emitting Device 1

In a light emitting device 1, one or plural light emitting elements 20 are arranged in the internal space of a package 10. The one or plural light emitting elements 20 are disposed on a base 11. The one or plural light emitting elements 20 are disposed on the first upper face 11A. The light emitting elements 20 emit light from the light emission faces 22 in a first direction. In the light emitting device 1 illustrated, the first direction coincides with the Y direction.

The one or plural light emitting elements 20 can be plural light emitting elements 20 that emit light of the same color. The one or plural light emitting elements 20 can be plural light emitting elements 20 including a first light emitting element and a second light emitting element that emit light of different colors from one another.

The plural light emitting elements 20 are lined up in one direction. The light emitting elements 20 are lined up in the second direction that is perpendicular to the first direction. The light emitting elements 20 emit light in the same direction. In the light emitting device 1 illustrated, light emitting elements 20 including at least five light emitting elements 20 are lined up in one direction. The second direction coincides with the positive X direction.

The one or plural light emitting elements 20 are disposed on one or plural submounts 30. The one or plural light emitting elements 20 are placed on the first upper face 11A via the one or plural submounts 30. One or more light emitting elements 20 are disposed on one submount 30. The light emitting element or each light emitting element 20 is disposed on the wiring layer 33 of the submount 30.

One of the electrodes of the light emitting element 20 or each light emitting element 20 is bonded to the wiring layer 33. The submount 30 or each submount 30 is electrically connected to the light emitting element 20 on this electrode side. For example, this electrode is anode, and the other electrode is cathode. Being on this electrode side means that the electrode is closer than the other electrode is. Similarly, being on the other electrode side means that the other electrode is closer than this electrode.

In a light emitting element 1, plural wires 60 are provided for electrically connecting one or plural light emitting elements 20 to the package 10. The wires 60 include one or plural wires 60 that are electrically connected to a light emitting element 20 on the first electrode side, and one or plural wires 60 that are electrically connected to the light emitting element 20 on the second electrode side. The wires 60 electrically connected to the one or plural light emitting elements 20, in terms of the relationship with a certain light emitting element 20, are either the wires 60 connected to the light emitting element 20 on the first electrode side or the second electrode side.

The wires 60 include one or plural wires 60 that are electrically connected to the light emitting elements 20 and bonded to the first wiring part 12A1. This allows the light emitting elements 20 to electrically connect to the first wiring part 12A1 and the second wiring part 12A2. This allows the light emitting elements 20 to receive power from an external power supply via the wiring parts 12A.

In the light emitting device 1, the first wiring part 12A1 serves as an element side wiring part, and the second wiring part 12A2 a power supply side wiring part. In a current path, the one of the first wiring part 12A1 and the second wiring part 12A2 that is closer to the light emitting element 20 is the element side wiring part, and the one that is closer to an external power supply is the power supply side wiring part.

The wires 60 include a first wire 60A and a second wire 60B that are electrically connected to a light emitting element 20 on the first electrode side. The first wire 60A and the second wire 20B are electrically connected to multiple light emitting elements 20. The first wire 60A is bonded to the first element side wiring part 12A11, and the second wire 60B is bonded to the second element side wiring part 12A12. The first element side wiring part 12A11 and the second element side wiring part 12A12 are element side wiring parts that are apart from one another. Bonding two wires 60 electrically connected to the light emitting elements 20 on the first electrode side to the wiring parts 12A in this manner can divide the current path in the base 11 on the first electrode side into two, thereby reducing the resistance when a current flows across the base 11.

The first element side wiring part 12A11 is electrically connected to the first power supply side wiring part 12A21. The second element side wiring part 12A2 is electrically connected to the second power supply side wiring part 12A22. The first power supply side wiring part 12A21 and the second power supply side wiring part 12A22 are power supply side wiring parts that are apart from one another.

The first element side wiring part 12A11 and the second element side wiring part 12A12 are not electrically connected to one another in the base 11. The first power supply side wiring part 12A21 and the second power supply side wiring part 12A22 are not electrically connected to one another in the base 11. This achieves total separation of the two current paths in the base 11 without allowing them to merge somewhere along the base 11.

The wires 60 include a third wire 60C that is electrically connected to a light emitting element 20 on the second electrode side. The third wire 60C is electrically connected to multiple light emitting elements 20. The third wire 60C is bonded to a third element side wiring part 12A13. The third element side wiring part 12A13 is electrically connected to a third power supply side wiring part 12A23.

In the base 11, the resistance value [Ω] from the first element side wiring part 12A11 to the first power supply wiring part 12A21 is higher than the resistance value [Ω] from the third element side wiring part 12A13 to the third power supply side wiring part 12A23. At this time, dividing the current path related to the first element side wiring part 12A11 is more effective in reducing the resistance than dividing the current path related to the third element side wiring part 12A13.

In the base 11, the number of current paths electrically connected to the light emitting elements 20 on the first electrode side is greater than the number of current paths electrically connected to the light emitting elements 20 on the second electrode side. Increasing the number of current paths can make the wiring structure in the base 11 complex as well as increasing the number of wires 60 used. These are desirably taken into consideration in adjusting the number of current path divisions so as to efficiently achieve the resistance reduction effect. In the light emitting device 1 illustrated, there is a single element side wiring part 12A1 electrically connected to the light emitting elements 20 on the second electrode side in the base 11, and the current path is not divided.

The first element side wiring part 12A11 is positioned apart from the one or plural light emitting elements 20 in the second direction. The first element side wiring part 12A 11 is disposed on the first outer lateral face 11D1 side among plural outer lateral faces 11D of the base 11. The first power supply side wiring part 12A21 is disposed on the second outer lateral face 11D2 side among plural outer lateral faces 11D of the base 11. The second outer lateral face 11D2 is the outer lateral face 11D that is located opposite the first outer lateral face 11D1.

The second element side wiring part 12A12 is positioned apart from the one or plural light emitting elements 20 in the positive second direction. The second element side wiring part 12A12 is disposed on the first outer lateral face 11D1 side. The second power supply side wiring part 12A22 is disposed on the second outer lateral face 11D2 side.

The third element side wiring part 12A13 is positioned apart from the one or plural light emitting elements 20 in the negative second direction. The third element side wiring part 12A13 is disposed on the second outer lateral face 11D2 side. The third power supply side wiring part 12A23 is disposed on the second outer lateral face 11D2 side. When viewed from above, the one or plural light emitting elements 20 are arranged between the first element side wiring part 12A11 and the third element side wiring part 12A13.

Disposing the first element side wiring part 12A11 and the second element side wiring part 12A12 on the same outer lateral face 11D side makes it easier to bond the first wire 60A and the second wire 60B, facilitating the utilization of two current paths in the base 11.

Disposing the first element side wiring part 12A11 and the third element side wiring part 12A13 on the opposing outer lateral face 11D sides makes it easier to bond multiple wires 60 for serially connecting plural light emitting elements 20. In the light emitting device 1 illustrated, plural light emitting elements 20 are connected in series.

Disposing the first power supply side wiring part 12A21 and the third power supply side wiring part 12A23 on the same outer lateral face 11D side can dispose multiple power source side wiring parts 12A2 in a consolidated manner. In return, in the base 11, the resistance value [Ω] from the first element side wiring part 12A11 to the first power supply wiring part 12A21 can be twice the resistance value [Ω] from the third element side wiring part 12A13 to the third power supply side wiring part 12A23 or higher.

Disposing the first power supply side wiring part 12A21 and the second power supply side wiring part 12A22 on the same outer lateral face 11D side makes it easier to connect the first power supply side wiring part 12A21 and the second power supply side wiring part 12A22 to the same electrode. For example, facilitating the connection of these power supply side wiring parts to one electrode part can realize a light emitting device 1 with easy wiring connection.

The power supply side wiring parts including the first power supply side wiring part 12A21, the second power supply side wiring part 12A22, and the third power supply side wiring part 12A23 are lined up in one direction. The second power supply side wiring part 12A22 is disposed next to the first power supply side wiring part 12A21. Locating the first power supply side wiring part 12A21 and the second power supply side wiring part 12A22 next to one another can facilitate the connection of these power supply side wiring parts to one electrode part, thereby achieving a light emitting device 1 with easy wire connection.

Dividing the current path on at least one electrode side in the base 11 into multiple paths can more effectively work for a red light emitting semiconductor laser element than a blue or green light emitting semiconductor laser element. If the resistance of the base 11 is high, the amount of heat generated in the base 11 would also increase to thereby reduce the heat dissipation performance of the base 11. Accordingly, the resistance reduction effect of divided current paths is more effective for a red semiconductor laser element with relatively poorer temperature characteristics than a blue or green light emitting semiconductor laser element.

Wires 60 include one or plural first wires 60A, one or plural second wires 60B, and plural third wires 60C. In a light emitting device 1, the number of third wires 60C bonded to the third element side wiring part 12A13 is greater than the number of first wires 60A bonded to the first element side wiring part 12A11. The number of third wires 60C bonded to the third element side wiring part 12A13 is greater than the number of second wires 60B bonded to the second element side wiring part 12A12.

The sum of the number of first wires 60A bonded to the first element side wiring part 12A11 and the number of second wires 60B bonded to the second element side wiring part 12A12 is equal to or greater than the number of third wires 60C bonded to the third element side wiring part 12A13. As such, the number of wires 60 bonded to each element side wiring part can be adjusted in accordance with the number of divided current paths.

The one or plural first wires 60A and the one or plural second wires 60B are bonded to a submount 30. One or plural third wires 60C are bonded to a light emitting element 20. The submount 30 to which the first wire 60A is bonded can be different from the submount 30 on which the light emitting element 20 is mounted and to which the third wires 60C are bonded. On this submount, the light emitting element 20 positioned at one end among the plural light emitting elements 20 lined up in the second direction is disposed. This light emitting element 20 is the one among the plural light emitting elements 20 lined up in the second direction that is positioned at the end in the negative second direction.

When viewed from above, the first wire or each first wire 60A is disposed between the first imaginary plane that includes the light emission face 22 of the light emitting element 20 and the second imaginary plane that includes the lateral face 21C opposing the light emission face 22 of the light emitting element 20. This light emitting element 20 is the one that is disposed on the submount 30 to which the first wire 60A is bonded.

When viewed from above, the one or each second wire 60B is disposed in the region that does not include the light emitting element 20 of the two regions divided by the second imaginary plane. This light emitting element 20 is disposed on the submount 30 to which the second wire 60B is bonded.

The first element side wiring part 12A11 and the first power supply side wiring part 12A21 are electrically connected via first via wiring 11Q1. The second element side wiring part 12A12 and the second power supply side wiring part 12A22 are electrically connected via second via wiring 11Q2. The third element side wiring part 12A13 and the third power supply side wiring part 12A23 are electrically connected via third via wiring 11Q3. The first via wiring 11Q1, the second via wiring 11Q2, and the third via wiring 11Q3 are individual via wiring 11Q.

The first via wiring 11Q1 has a first via part 11R1 and a first wiring layer 11S1. The second via wiring 11Q2 has a second via part 11R2 and a second wiring layer 11S2. The third via wiring 11Q3 has a third via part 11R3 and a third wiring layer 11S3. The first via part 11R1, the second via part 11R2, and the third via part 11R3 are individual via parts 11R. The first wiring layer 11S1, the second wiring layer 11S2, and the third wiring layer 11S3 are individual wiring layers 11S.

In the base 11, the first via wiring 11Q1 and the second via wiring 11Q2 are not electrically connected. In the base 11, the first via wiring 11Q1, the second via wiring 11Q2, and the third via wiring 11Q3 are not electrically connected to one another.

The first via wiring 11Q1 is connected to the first power supply side wiring part 12A21. The first via wiring 11Q1 can further be connected to a fourth power supply side wiring part. The fourth power supply side wiring part can be disposed on the outer lateral face 11D side located opposite the side where the first power supply side wiring part 12A 21 is provided (the first outer face 11D1 side). This allows for a selective use of a power supply side wiring part disposed on either outer lateral face 11D side in achieving an electrical connection to an external power supply.

The second via wiring 11Q2 is connected to the second power supply side wiring part 12A22. The second via wiring 11Q2 can further be connected to a fifth power supply side wiring part. The fifth power supply side wiring part can be disposed on the outer lateral face 11D side located opposite the side where the second power supply side wiring part 12A22 is provided (the first outer face 11D1 side). The third via wiring 11Q3 is connected to the third power supply side wiring part 12A23. The third via wiring 11Q3 can further be connected to a sixth power supply side wiring part. The sixth power supply side wiring part can be disposed on the outer lateral face 11D side located opposite the side where the third power supply side wiring part 12A23 is provided (the first outer face 11D1 side).

The base 11 can further have, as an element side wiring part, a fourth element side wiring part 12A14 disposed on the second outer lateral face 11D2 side. It can further have, as a power supply side wiring part, a seventh power supply side wiring part electrically connected to the fourth element side wiring part 12A14 and disposed on the first outer lateral face 11D1 side. This allows the third element side wiring part 12A13 and the fourth element side wiring part to be used in leu of the first element side wiring part 12A11 and the second element side wiring part 12A12 as the first wiring parts 12A1 that divide the current path.

In the light emitting device 1 illustrated, the wires 60 bonded to the first element side wiring part 12A11 (first wires 60A), the wires 60 bonded to the second element side wiring part 12A12 (second wires 60B), and the wires 60 bonded to the third element side wiring part 12A13 (third wires 60C) are present, but the wires 60 bonded to the fourth element side wiring part 12A14 are not.

In the light emitting device 1, one or plural light reflecting members 40 are arranged in the inner space of the package 10. The one or plural reflecting members 40 are disposed on the base 11. The one or plural reflecting members 40 are disposed on the first upper face 11A. The one or plural reflecting members 40 are positioned apart from the one or plural light emitting elements 20 in the first direction. The one or plural reflecting members 40 reflect the light emitted by the one or plural light emitting elements 20. The light reflected by the one or plural reflecting members 40 is output upwards from the upper face 14A of the package 10.

In the light emitting device 1, one or more protective devices 50 are arranged in the inner space of the package 10. The one or more protective devices 50 are disposed on the first wiring part 12A1 of the package 10. The one or more protective devices 50 protect the one or plural light emitting elements 20.

The one or more protective devices 50 include at least a protective device 50 disposed on the second stepped portion 11F2. The one or more protective devices 50 include at least a protective device 50 electrically connected to the fifth element side wiring part 12A15 disposed on the second outer face 11D2 side. This protective device 50 is disposed on the fifth element side wiring part 12A15. This protective device 50 is disposed on the third element side wiring part 12A13.

In the base 11, the fifth element side wiring part 12A15 is electrically connected to the second power supply side wiring part 12A22. In the base 11, the fifth element side wiring part 12A15, together with the second element side wiring part 12A12, is electrically connected to the second power supply side wiring part 12A22. In other words, in the base 11, the fifth element side wiring part 12A15 is in the state of being electrically connected to the second element side wiring part 12A12.

In a light emitting device 1, an optical member 70 is placed above the package 10. The optical member 70 is fixed to the package 10. The optical member 70 is bonded to the lid 14 via an adhesive.

The optical member 70 is aligned towards the outer lateral face 11D on the positive first direction side of the package 10 of the two outer lateral faces 11D on the positive and negative sides in the first direction. When viewed from above, with respect to the first direction, the distance from the outer lateral face 11D on the negative first direction side to the optical member 70 is greater than the distance from the optical member 70 to the outer lateral face 11D on the positive first direction side.

The positions at which the second wires 60B are bonded to the second element side wiring part 12A12 do not overlap the optical member 70 when viewed from above. Designing a light emitting device 1 such that the second wires 60B are bonded at the position of the lid 14 which is translucent allows for a visual confirmation of the bonding or bonded state of the second wires 60B when a light emitting device 1 is manufactured. Even if the second wires 60B were not properly bonded, the current path is formed by the first wires 60A. Thus, whether or not the second wires 60B are bonded cannot be determined at the time of checking the electrical connection of the light emitting elements 20 on occasion. In such a case, it increases the benefit of being able to visually confirm the bonding of the second wires 60B.

The second element side wiring part 12A12 is positioned apart from the first element side wiring part 12A11 in the third direction. The submount 30 to which the second wires 60B are boded has a region R1 extending from the light emitting element 20 in the third direction when viewed from above (see FIG. 15). The region R1 at least has a width of 200 μm or larger in the third direction. This can facilitate the bonding of the second wires 60B to the region R1. Setting this width to 400 μm or larger can facilitate the bonding of multiple second wires 60B to the region R1.

The second wires 60B are bonded to the submount 30 in the region R1. This can reduce the lengths of the second wires 60B, thereby reducing the resistance of the second wires 60B.

The light exiting the package enters the optical member 70. The light hits the optical action face 71D of the optical member 70 and is subjected to an optical action before exiting the optical member 70. The light exiting the optical member 70 is the light output from the light emitting device 1. For example, light collimated by the lens face 71D is output from the light emitting device 1.

### Second Embodiment

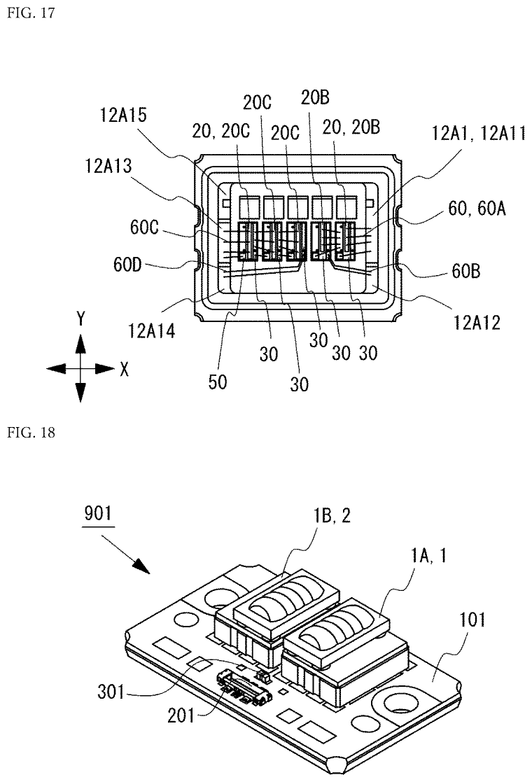

A light emitting device 2 related to a second embodiment will be explained. FIG. 1 to FIG. 4, FIG. 7 to FIG. 14, and FIG. 17 are drawings for explaining an exemplary form of the light emitting device 2. FIG. 1 is a perspective view of the light emitting device 2. FIG. 2 is a top view of the light emitting device 2. FIG. 3 is a side view of the light emitting device 2 viewed from the positive Y direction. FIG. 4 is a cross-sectional view of the light emitting device 2 taken along line IV-IV in FIG. 2. FIG. 7 is a perspective view of a package 10. FIG. 8 is a top view of the package 10. FIG. 9 is a cross-sectional view of the package 10 taken alone line IX-IX in FIG. 8. FIG. 10 is a cross-sectional view of the package taken along line X-X in FIG. 8. FIG. 11 is a top view of a base 11. FIG. 12 is a bottom view of the base 11. FIG. 13 is a cross-sectional view of the base 11 taken along line XIII-XIII in FIG. 11. FIG. 14A is an enlarged view enlarging FIG. 13 in the Z direction for explaining the stack structure LS of the base 11. FIG. 14B is a top view of a first insulation member 11P1 in the stack structure LS of the base 11. In FIG. 14B, the positions of the inner lateral faces 11E of the base 11 are indicated with broken lines for ease of understanding the positions of the element side wiring parts. FIG. 14C is a top view of an insulation member 11P disposed directly under the first insulation member 11P1. FIG. 14D is a top view of an insulation member 11P disposed directly under the insulation member 11P in FIG. 14C. In FIG. 14D, the locations of first to fourth power supply side wiring parts 12A21 to 12A24 are shown using broken lines for ease of understanding the locations of the power supply side wiring parts. FIG. 14E is a bottom view of a second insulation member 11P2. FIG. 17 is a top view showing the constituent elements in the package 10 of the light emitting device 2.

The description related to the light emitting device 1 and the constituent elements of the first embodiment provided above applies as the description of the light emitting device 2 except for the content that is considered inconsistent with FIG. 1 to FIG. 4, FIG. 7 to FIG. 14, and FIG. 17 for the light emitting device 2. All content that is not inconsistent will not be repeated here to avoid redundancy.

The light emitting device 2, unlike the light emitting device 1, does not have a structure in which the current path is divided by the first wires 60A and the second wires 60B. In the light emitting device 1, the first element side wiring part 12A11 and the second element side wiring part 12A12 are both used for electrical connection on the first electrode side. In the light emitting device 2, one of them is used for electrical connection on the first electrode side, and the other is used for electrical connection on the second electrode side. The same base 11 can be used for the light emitting device 1 and the light emitting device 2. The base 11 having the same wiring part 12A structure is utilized to achieve electrical connection.

The ability to utilize the same wiring part 12A structure in different wire connection forms as described above can improve productivity. Accordingly, a light emitting device manufacturer can suitably manufacture both light emitting devices 1 (first light emitting devices) and light emitting devices 2 (second light emitting devices). Manufacturing both does not mean the timing of manufacturing being simultaneous, but rather the selling period of the first light emitting devices and the selling period of the second light emitting devices being not far apart, preferably the selling periods of the two overlapping, such that a manufacturer can enjoy the benefit of increased productivity as long as it uses the base 11 having the same wiring part 12A structure in manufacturing the first light emitting devices and the second light emitting devices. Similarly, a person who transfers or exports light emitting devices to a third party such as a customer (hereinafter referred to as a provider) can suitably transfer or export both the first and second light emitting devices. It can be said that the benefit of increased productivity can be enjoyed by a provider as long as the provider purchases the first and second light emitting devices from the same supplier not only in the case of transferring or exporting the first and second light emitting devices to the same customers, but also the case of transferring or exporting the first and second light emitting devices to different customers.

### Light Emitting Device 2

In a light emitting device 2, one or plural light emitting elements 20 include a second light emitting element 20B that emits light of a different peak wavelength from that of a first light emitting elements 20A. The first light emitting element 20A is a light emitting element 20 included in the light emitting device 1. The second light emitting element described with reference to the light emitting device 1 of the first embodiment may be a light emitting element 20 emitting light of the same peak wavelength as or different peak wavelength from that of the second light emitting elements 20B in the light emitting device 2.

The one or plural light emitting elements 20 include a third light emitting element 20C emitting light of a different peak wavelength from that of the first light emitting element 20A. The third light emitting element 20C emits light having a different peak wavelength from that of the second light emitting element 20B.

The first light emitting element 20A, the second light emitting element 20B, and the third light emitting element 20C each emit light of a different color among red, green, and blue light. This allows a light emitting module including a first light emitting device and a second light emitting device to emit RGB light.

In the light emitting device 2, the one or plural light emitting elements 20 can be made up of those that include one or plural second light emitting elements 20B and one or plural third light emitting elements 20C. The light emitting device 2 illustrated include five or more light emitting elements 20 including two or more second light emitting elements 20B and three or more third light emitting elements 20C.

In the light emitting device 2, the wires 60 include a first wire 60A electrically connected to the one or plural second light emitting elements 20B on the first electrode side, and a second wire 60B electrically connected to the one or plural second light emitting elements 20B on the second electrode side. The first wire 60A is bonded to the first element side wiring part 12A11, and the second wire 60B is bonded to the second element side wiring part 12A12. This allows the first element side wiring part 12A11 and the second element side wiring part 12A12 to be utilized not only for branching the current path on the same electrode side, but also electrically connecting the first electrode and the second electrode of the light emitting elements 20.

In the light emitting device 2, the wires 60 include a third wire 60C electrically connected to one or plural third light emitting elements 20C on the first electrode side, and a fourth wire 60D electrically connected to the one or plural third light emitting elements 20C on the second electrode side. The third wire 60C is bonded to the third element side wiring part 12A13, and the fourth wire 60D is bonded to the fourth element side wiring part 12A14. This allows two element side wiring parts disposed on one outer lateral face 11D side to electrically connect the second light emitting element 20B to the base 11, and two element side wiring parts to electrically connect the third light emitting element 20C disposed on another outer lateral face 11D side to the base 11, facilitating the bonding of wires 60.

### Third Embodiment

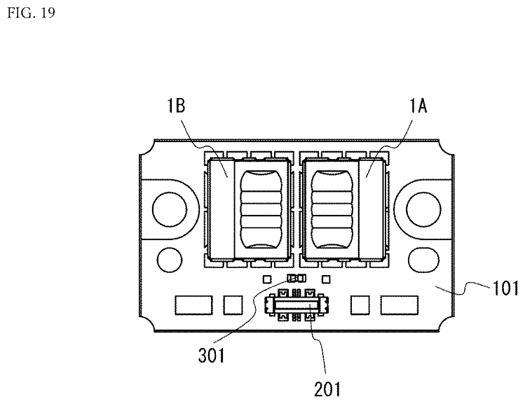

A light emitting module 901 related to a third embodiment will be explained. FIG. 1 to FIG. 19 are drawings for explaining an exemplary form of light emitting module 901. FIG. 1 to FIG. 17 illustrate the light emitting device 1 and the light emitting device 2 included in the light emitting module 901, and are as explained above. FIG. 18 is a perspective view of the light emitting module 901. FIG. 19 is a top view of the light emitting module 901.

The light emitting module 901 includes plural constituent elements. The constituent elements of the light emitting module 901 include plural light emitting devices, a wiring board 101, a connector 201, and a thermistor 301.

The light emitting module 901 may include an additional constituent element. For example, the light emitting module 901 may include a light emitting device that is different from a light emitting device 1. The light emitting module 901 is allowed to not include a certain constituent element among those listed above.

The light emitting devices included in the light emitting module 901 include a first light emitting device 1A and a second light emitting device 1B. In the light emitting module 901 illustrated, a light emitting device 1 of the first embodiment is employed as the first light emitting device 1A, and a light emitting device 2 of the second embodiment is employed as the second light emitting device 1B. As the light emitting device 1 and the light emitting device 2 have already been explained in the embodiments above, the description is not repeated here.

### Light Emitting Module 901

In a light emitting module 901, a first light emitting device 1A and a second light emitting device 1B are mounted on a wiring board 101. The light emitting module 901 has one or plural first light emitting elements 20A, one or plural second light emitting elements 20B, and one or plural third light emitting elements 20C. This can realize a light emitting module 901 that outputs RGB light.

The first light emitting device 1A can include one or plural first light emitting elements 20A, the second light emitting device 1B can include one or plural second light emitting elements 20B and one or plural third light emitting elements 20C.

In the foregoing, certain embodiments of the present invention have been explained. The light emitting device and light emitting module according to the present invention, however, are not strictly limited to the light emitting device and the light emitting module of the embodiments disclosed. In other words, the present invention is implementable without limiting the outer shape or the structure of a light emitting device or light emitting module to any of those disclosed by the embodiments. The present invention can be implemented without making it essential to include all of the constituent elements. For example, in the event that a certain constituent element of a light emitting device disclosed by any of the embodiments is not disclosed in the claim scope, we claim the applicability of the invention disclosed in the claim scope by recognizing the design flexibility for a person of ordinary skill in the art for such a constituent element through the use of an alternative, an omission, a shape change, a change in the materials employed, or the like.

The light emitting device and light emitting module according to the embodiments can be used in a projector. In other words, a projector is one form of use to which the present invention is applied. Not limited to this, the present invention can be utilized in various forms of use, such as lighting fixtures, exposure systems, automotive headlights, head-mounted displays, backlights for displays, and the like.

What is claimed is:

1. A light emitting device comprising:
a plurality of light emitting elements each having a first electrode and a second electrode, and emitting light in a first direction;
a base having a plurality of wiring parts including a first element side wiring part, a second element side wiring part, a third element side wiring part, a first power supply side wiring part electrically connected to the first element side wiring part, a second power supply side wiring part electrically connected to the second element side wiring part, and a third power supply side wiring part electrically connected to the third element side wiring part, on which the plurality of light emitting elements are lined up in the positive second direction that is perpendicular to the first direction; and
a plurality of wires including a first wire and a second wire electrically connected to the light emitting elements on the first electrode side, and a third wire electrically connected to the light emitting elements on the second electrode side, wherein
the first element side wiring part and the second element side wiring part are positioned apart from the light emitting elements in the positive second direction,
the third element side wiring part is positioned apart from the light emitting elements in the negative second direction, and
the first wire is bonded to the first element side wiring part, the second wire is bonded to the second element side wiring part, and the third wire is bonded to the third element side wiring part.

2. The light emitting device according to claim 1, wherein
the base has a first outer lateral face and a second outer lateral face located opposite the first outer lateral face,
the first element side wiring part and the second element side wiring part are disposed on the first outer lateral face side, and
the third element side wiring part is disposed on the second outer lateral face side.

3. The light emitting device according to claim 2 wherein the light emitting elements are arranged between the first element side wiring part and the third element side wiring part when viewed from above.

4. The light emitting device according to claim 1 further comprising one or plural submounts on which the light emitting elements are mounted, wherein
the first wire and the second wire are bonded to the submounts, and
the third wire is bonded to the light emitting element.

5. The light emitting device according to claim 4, wherein
the first wire is disposed between the first imaginary plane that includes the light emission face of a light emitting element and the second imaginary plane that includes the lateral face opposite the light emission face when viewed from above, and
the second wire is disposed in the region that does not include the light emitting element 20 of the two regions divided by the second imaginary plane when viewed from above.

6. The light emitting device according to claim 1, wherein
the base has a stack structure in which plural insulation members including at least a first insulation member and a second insulation member are stacked,
the first element side wiring part, the second element side wiring part, and the third element side wiring part are disposed on the first insulation member,
the first power supply side wiring part, the second power supply side wiring part, and the third power supply side wiring part are disposed on the second insulation member,
the first element side wiring part and the first power supply side wiring part are electrically connected via first via wiring provided in the stack structure,
the second element side wiring part and the second power supply side wiring part are electrically connected via second via wiring provided in the stack structure,
the third element side wiring part and the third power supply side wiring part are electrically connected via third via wiring provided in the stack structure, and
the first via wiring, the second via wiring, and the third via wiring are not electrically connected to one another in the stack structure.

7. The light emitting device according to claim 6 wherein
the first via wiring has a first via part that goes through the insulation members in the stacking direction and a first wiring layer that is connected to the first via part and extending in the planar direction of the insulation members that is perpendicular to the stacking direction, and
the second via wiring has a second via part that goes through the insulation members in the stacking direction and a second wiring layer that is connected to the second via part and extending in the planar direction of the insulation members that is perpendicular to the stacking direction.

8. A first light emitting device and a second light emitting device each including a base that has a plurality of wiring parts including a first element side wiring part, a second element side wiring part, a first power supply side wiring part electrically connected to the first element side wiring part, and a second power supply side wiring part electrically connected to the second element side wiring part,
the first light emitting device comprising:
one or plural first light emitting elements each having a first electrode and a second electrode,
the base on which the one or plural first light emitting elements are disposed, and
a plurality of wires including a first wire and a second wire electrically connected to the one or plural first light emitting elements on the first electrode side,
the first wire being bonded to the first element side wiring part and the second wire being bonded to the second element side wiring part,
the second light emitting device comprising:
one or plural second light emitting elements each having a first electrode and a second electrode,
the base on which the one or plural second light emitting elements are disposed, and
a plurality of wires including a first wire electrically connected to the one or plural second light emitting elements on the first electrode side and a second wire electrically connected to the one or plural second light emitting elements on the second electrode side,
the first wire being bonded to the first element side wiring part and the second wire being bonded to the second element side wiring part, wherein
the first light emitting element and the second light emitting element emitting light of different peak wavelengths from one another.

9. The first light emitting device and the second light emitting device according to claim 8, wherein
the plural wiring parts in the base further comprise a third element side wiring part, a fourth element side wiring part, a third power supply side wiring part electrically connected to the third element side wiring part, and a fourth power supply side wiring part electrically connected to the fourth element side wiring part,
the wires included in the first light emitting device further include a third wire electrically connected to the one or plural first light emitting elements on the second electrode side,
the third wire included in the first light emitting device is bonded to the third element side wiring part,
the second light emitting device further includes one or plural third light emitting elements each having a first electrode and a second electrode,
the wires included in the second light emitting device further include a third wire electrically connected to the one or plural third light emitting elements on the first electrode side, and a fourth fire electrically connected to the one or plural third light emitting elements on the second electrode side,
the third wire included in the second light emitting device is bonded to the third element side wiring part,
the fourth wire included in the second light emitting device is bonded to the fourth element side wiring part, and
the first light emitting element, the second light emitting element, and the third light emitting element emit light of different peak wavelengths from one another.

10. The first light emitting device and the second light emitting device according to claim 9, wherein there is no wire that is bonded to the fourth element side wiring part in the first light emitting device.

11. A light emitting module comprising:
a first light emitting device and a second light emitting device disclosed in claim 8, and
a wiring board on which the first light emitting device and the second light emitting device are mounted.

12. A light emitting module comprising:
a first light emitting device and a second light emitting device disclosed in claim 9 or 10, and
a wiring board on which the first light emitting device and the second light emitting device are mounted, wherein
the first light emitting element, the second light emitting element, and the third light emitting element emit light of different colors from one another among red, green, and blue light.
